(19) United States
(12) Patent Application Publication
(10) Pub. No.: US 2026/0227655 A1
(43) Pub. Date: Aug. 6, 2026

(54) ELECTRONIC DEVICE

(71) Applicant: InnoLux Corporation, Miao-Li County (TW)

(72) Inventors: Huang-Cho CHEN, Miao-Li County (TW); Jui-Chu LAI, Miao-Li County (TW); Kuo-Liang CHUANG, Miao-Li County (TW)

(73) Assignee: InnoLux Corporation, Miao-Li County (TW)

(21) Appl. No.: 19/438,669

(22) Filed: Jan. 2, 2026

(30) Foreign Application Priority Data
Feb. 6, 2025 (CN) 202510131488.X

(51) Int. Cl. G02F 1/1335; G02F 1/133; H10D 86/40

(52) U.S. Cl. CPC G02F 1/133512; G02F 1/13306; G02F 1/133514; H10D 86/441

(57) ABSTRACT

An electronic device include a substrate, a driving circuit disposed on the substrate, a first shielding pattern, a second shielding pattern, a first organic layer, and a conductive layer. The first shielding pattern is disposed on the driving circuit and includes a first opening. The first organic layer is disposed on the first shielding pattern and includes a second opening overlapping the first opening. The conductive layer is electrically connected with the driving circuit via the first opening and the second opening. The second shielding pattern is disposed in the first opening and the second opening.

### BACKGROUND OF THE DISCLOSURE

### Field of the Disclosure

The present disclosure relates to an electronic device, and particularly to an electronic device including a shielding pattern disposed on a driving circuit.

### Description of the Prior Art

In electronic devices such as virtual reality (VR) devices, augmented reality (AR) devices, and liquid crystal display devices, products with small pixel sizes have higher requirements for the alignment accuracy and patterning design of the light filtering layer and the light shielding pattern.

### SUMMARY OF THE DISCLOSURE

An electronic device is provided in an embodiment of this disclosure. The electronic device includes a substrate, a driving circuit, a first shielding pattern, a first organic layer, a conductive layer, and a second shielding pattern. The driving circuit is disposed on the substrate. The first shielding pattern is disposed on the driving circuit and includes a first opening. The first organic layer is disposed on the first shielding pattern and includes a second opening overlapping the first opening. The conductive layer is electrically connected with the driving circuit via the first opening and the second opening, and the second shielding pattern is disposed in the first opening and the second opening.

An electronic device is provided in another embodiment of this disclosure. The electronic device includes a substrate, a driving circuit, a first organic layer, a conductive layer, a first shielding pattern, and a second shielding pattern. The driving circuit is disposed on the substrate. The first organic layer is disposed on the driving circuit and includes a first opening and a second opening. The conductive layer is electrically connected with the driving circuit via the second opening. The first shielding pattern and the second shielding pattern are disposed in the first opening and the second opening, respectively. A depth of the first opening is different from a depth of the second opening.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a top-view schematic diagram illustrating a part of an electronic device according to an embodiment of the present disclosure.

FIG. 2 is another top-view schematic diagram illustrating a part of an electronic device according to an embodiment of the present disclosure.

FIG. 3 is a cross-sectional schematic diagram illustrating a part of an electronic device according to a first embodiment of the present disclosure.

FIG. 4 is a cross-sectional schematic diagram illustrating a part of an electronic device according to a second embodiment of the present disclosure.

FIG. 5 is a cross-sectional schematic diagram illustrating a part of an electronic device according to a third embodiment of the present disclosure.

FIG. 6 is a cross-sectional schematic diagram illustrating a part of an electronic device according to a fourth embodiment of the present disclosure.

FIG. 7 is a cross-sectional schematic diagram illustrating a part of an electronic device according to a fifth embodiment of the present disclosure.

FIG. 8 is a cross-sectional schematic diagram illustrating a part of an electronic device according to a sixth embodiment of the present disclosure.

FIG. 9 is a cross-sectional schematic diagram illustrating a part of an electronic device according to a seventh embodiment of the present disclosure.

FIG. 10 is a cross-sectional schematic diagram illustrating a part of an electronic device according to an eighth embodiment of the present disclosure.

### DETAILED DESCRIPTION

The present disclosure may be understood by referring to the following detailed description, taken in conjunction with the drawings as described below. It is noted that, certain elements in various drawings may not be drawn to scale. In addition, the number and dimension of each element shown in drawings are only illustrative and are not intended to limit the scope of the present disclosure.

Certain terms are used throughout the description and claims to refer to particular elements. As one skilled in the art will understand, manufacturers may refer to an element by different names. This disclosure does not intend to distinguish between elements that differ in name but not function. In the following description and in the claims, the terms “include”, “comprise” and “have” are used in an open-ended fashion, and thus should be interpreted to mean “include, but not limited to...”.

When an element or a layer is referred to as being “disposed on” or “connected to” another element or layer, it can be directly on or directly connected to the other element or layer, or intervening elements or layers may be presented (indirectly). When an element or a layer is referred to as being “coupled” to another element or layer, it can be a direct electrical connection or an indirect electrical connection.

Although terms such as first, second, etc., may be used to describe diverse elements, such elements are not limited by the terms. The terms are used only to discriminate an element from other elements in the specification. The claims may not use the same terms, but instead may use the terms first, second, etc. with respect to the order in which an element is claimed. Accordingly, in the following description, a first element may be a second element in a claim.

The terms “equal to”, “equal”, “the same”, “approximately” or “substantially” are generally interpreted as being within ± 10%, ± 5%, ± 3%, ± 2%, ± 1%, or ± 0.5% of the given value.

Unless additionally defined, all terms (including technical and scientific terms) used herein have the same meaning as commonly understood by those ordinary skilled in the art. Terms that are defined in commonly used dictionaries should be interpreted as having meanings consistent with the relevant art and the present disclosure, and should not be interpreted in an idealized or overly formal manner, unless specifically defined.

It should be noted that the following embodiments may be implemented by replacing, reorganizing, or mixing the technical features of different embodiments without departing from the spirit of the present disclosure to complete other embodiments.

The electronic device described in the present disclosure may be applied in a display device, a virtual reality device, an augmented reality device, or a light-emitting device, but not limited thereto. The display device may be a non-self-luminous display device or a self-luminous display device. In the following description, the display device is taken as an example included in the electronic device to describe the contents of the present disclosure, but the present disclosure is not limited thereto.

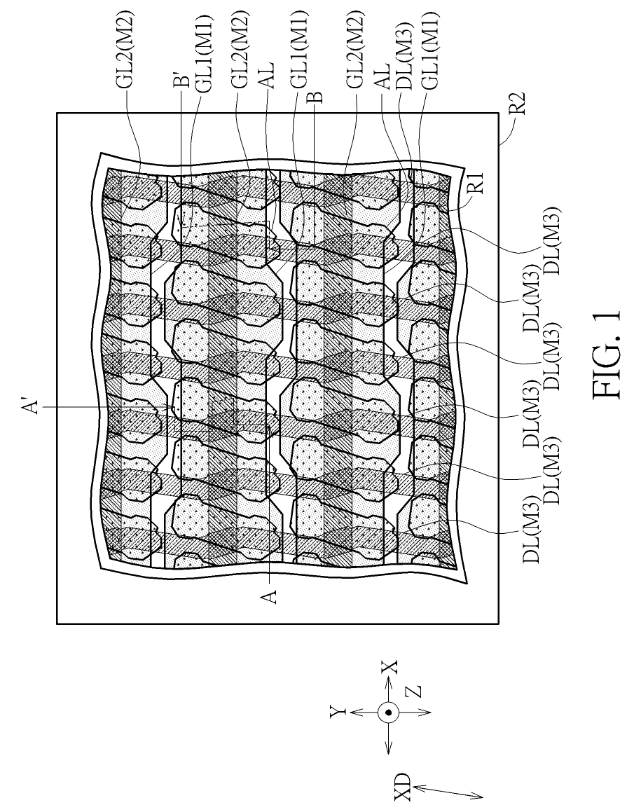

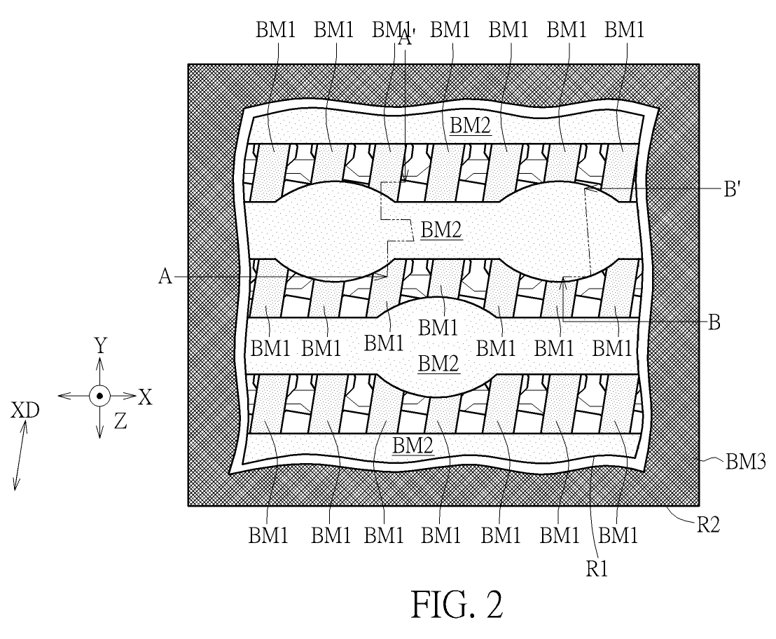

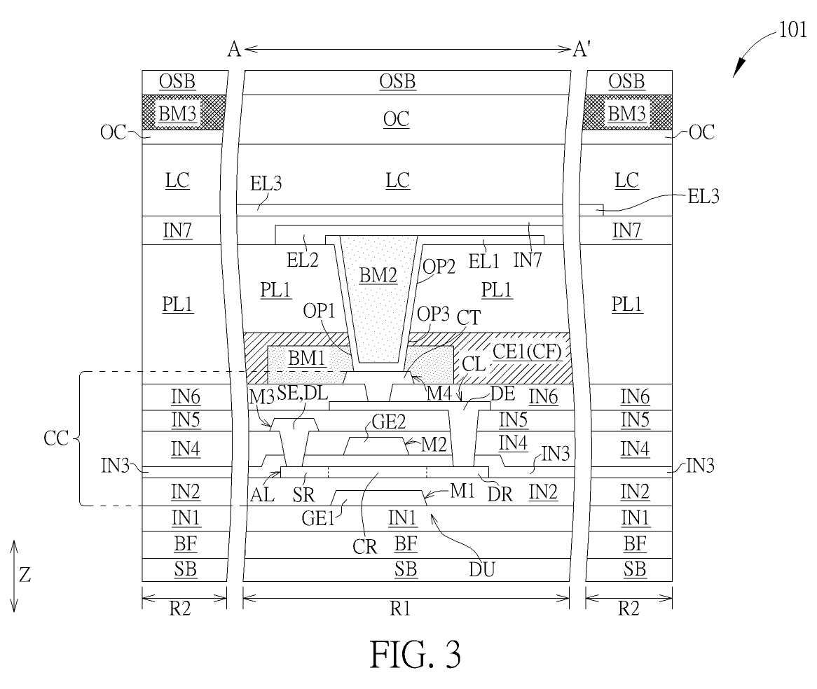

Please refer to FIG. 1 and FIG. 2. FIG. 1 and FIG. 2 show only some components. FIG. 2 may be regarded as a top-view schematic diagram of the situation of FIG. 1 with added shielding patterned. Additionally, a part of FIG. 3 may be regarded as a cross-sectional schematic diagram taken along a line A-A’ in FIG. 1 and/or a line A-A’ in FIG. 2. As shown in FIG. 1 and FIG. 2, the electronic device may include a first region R1 and a second region R2 surrounding the first region R1.The first region R1 may be regarded as a central region and/or a display region, and the second region R2 may be regarded as a peripheral region and/or a non-display region. The electronic device may include a plurality of scan lines GL1, a plurality of scan lines GL2, a plurality of data lines DL, and a plurality of active layers AL disposed in the first region R1. Each of the scan lines GL1 may extend in a direction X substantially, and may be formed of at least a part of a conductive layer M1. Each of the scan lines GL2 may extend in the direction X substantially, and may be formed of at least a part of a conductive layer M2. Each of the data lines DL may extend in a direction Y, and may be formed of at least a part of a conductive layer M3. A part of each of the data lines DL may extend in an oblique direction (such as a direction XD) which is not parallel to the direction X and the direction Y. The directions X, Y, and XD may be regarded as horizontal directions substantially orthogonal to a vertical direction (such as a direction Z), and the direction X may be substantially orthogonal to the direction Y. The electronic device may further include a plurality of shielding patterns BM1, a plurality of shielding patterns BM2, and a shielding pattern BM3. The shielding patterns BM1, BM2, and BM3 may have higher optical density (OD) for providing light-shielding effect. The shielding patterns BM1, BM2, and BM3 are positioned to correspond with the data lines DL, the scan lines GL2, and the second region R2, respectively. The “optical density” in the present disclosure refers to the light-shielding ability of a material or a component. The higher optical density means the better light-shielding ability.

Please refer to FIGS. 1-3. The electronic device 101 includes a substrate SB, a driving circuit DU, a first shielding pattern (such as BM1), a first organic layer PL1, a conductive layer EL1, and a second shielding pattern (such as BM2). The driving circuit DU is disposed on the substrate SB. The shielding pattern BM1 is disposed on the driving circuit DU and includes a first opening (such as OP1). The first organic layer PL1 is disposed on the shielding pattern BM1and includes a second opening (such as OP2) overlapping the opening OP1. The conductive layer EL1 is electrically connected with the driving circuit DU via the opening OP1 and the opening OP2, and the shielding pattern BM2 is disposed in the opening OP1 and the opening OP2. The electronic device 101 may further include a light filtering layer CF disposed on the substrate SB. The light filtering layer CF may include a plurality of light filtering units (such as CE1) disposed corresponding to different sub pixel regions. A part of the light filtering layer CF may be disposed between the shielding pattern BM1 and the first organic layer PL1 in the direction Z. In addition, the light filtering layer CF may include a third opening (such as OP3) overlapping the opening OP2, and the shielding pattern BM2 may be further disposed in the opening OP3.The openings OP1, OP3, and OP2 are overlapped with one another in the direction Z. The conductive layer EL1 may be partly disposed in the openings OP1, OP3, and OP2 and partly disposed on a top surface of the first organic layer PL1. The shielding pattern BM2 may be disposed on the conductive layer EL1 and disposed in the opening OP1, OP2, and OP3. A top surface of the shielding pattern BM2 and a top surface of the conductive layer EL1 may be substantially coplanar, but not limited thereto. The top surface of the shielding pattern BM2 may be slightly higher than the top surface of the conductive layer EL1, slightly lower than the top surface of the conductive layer EL1, or even slightly lower than the top surface of the first organic layer PL1. In this description, an opening in a specific component or a specific layer may include a through hole or a recess.

The electronic device 101 may include a circuit layer CC disposed on the substrate SB. The driving circuit DU may be regarded as a part of the circuit layer CC, and the circuit layer CC may include multiple insulation layers (such as insulation layers IN2, IN3, IN4, IN5, and IN6), conductive layers (such as an conductive layer M1, M2, M3, CL, and M4), and the active layer AL. The conductive layer M1 may include a gate electrode GE1, the gate electrode GE1 may be connected with the scan line GL1 or be regarded as a part of the scan line GL1, and the insulation layer IN2 may be disposed between the active layer AL and the conductive layer M1. The active layer AL may be disposed on the insulation layer IN2, and the insulation layer IN3 may be disposed between the active layer AL and the conductive layer M2. The conductive layer M2 may include a gate electrode GE2 and be disposed on the insulation layer IN3. The gate electrode GE2 may be connected with the scan line GL2 or be regarded as a part of the scan line GL2, and the insulation layer IN4 may cover the conductive layer M2. The active layer AL may include a channel region CR, a source region SR, and a drain region DR. The channel region CR may be defined as a part of the active layer AL overlapping the gate electrode GE1 and/or the gate electrode GE2. The active layer AL may include silicon or metal oxide, or other suitable semiconductor materials. The conductive layer M3 may include the data line DL electrically connected with the source region SR, a part of the data line DL may be regarded as a source electrode SE, and the source electrode SE may be electrically connected with the source region SR. The insulation layer IN5 may cover the insulation layer IN4 and the conductive layer M3, the conductive layer CL may include a drain electrode DE electrically connected to the drain region DR. The insulation layer IN6 may cover the insulation layer IN5 and the conductive layer CL, and the conductive layer M4 may include a contact element CT penetrating through the insulation layer IN6 for being electrically connected with the drain electrode DE. In an embodiment of the present disclosure, the conductive layer M1 may be used as a light shielding layer for improving the condition that the channel region CR deteriorates due to exposure to external ambient light.

The circuit layer CC may be disposed in the first region R1 and the second region R2. At least a part of the driving circuit DU may be disposed in the first region R1 and include the gate electrode GE1, the insulation layers IN2-IN6, the active layer AL, the gate electrode GE2, the source electrode SE (and/or the data line DL), the drain electrode DE, and the contact element CT described above. The shielding pattern BM1, the shielding pattern BM2, the light filtering layer CF, and the first organic layer PL1 may be disposed on the circuit layer CC. At least a part of the shielding pattern BM1, the shielding pattern BM2, and the light filtering layer CF are disposed in the first region R1, and the first organic layer PL1 may be disposed partly in the first region R1 and the second region R2. The electronic device 101 may further include a buffer layer BF disposed between the substrate SB and the circuit layer CC, and an insulation layer IN1 disposed between the buffer layer BF and the conductive layer M1. The openings OP1, OP3, and/or OP2 may overlap the contact element CT, and the conductive layer EL1 may contact and be electrically connected with the contact element CT via the openings OP2, OP3, and OP1. The circuit layer CC may not include the conductive layer M4, and the conductive layer EL1 may contact and being electrically connected with the conductive layer CL, but not limited thereto.

The electronic device 101 may further include a conductive layer EL2, an insulation layer IN7, and a conductive layer EL3. The conductive layer EL2 may be disposed on the first organic layer PL1. The insulation layer IN7 may be disposed on the conductive layer EL2, and the conductive layer EL3 may be disposed on the insulation layer IN7. The conductive layer EL2 may contact and be electrically connected with the conductive layer EL1, the conductive layer EL2 may be used as a pixel electrode, the conductive layer EL1 may be used as a connecting electrode electrically connecting the conductive layer EL2 and the contact element CT, and the conductive layer EL3 may be used as a common electrode. The negative influence of misalignments occurred during combining the substrate SB and a counter substrate OSB, such as decreasing aperture ratio, may be reduced by disposing the shielding pattern BM1 and the shielding pattern BM2 on a side of the array substrate, the distance between the shielding pattern and the material generating reflection may be further reduced by the shielding pattern BM1 and the shielding pattern BM2 disposed in the openings, and the light shielding effect may be enhanced accordingly for reducing light leakage. In addition, the shielding pattern BM2 may also be regarded as a replacement for an insulation material formed in the opening connecting the conductive layer EL1 and the driving circuit DU, and the overall manufacturing process steps may be simplified accordingly for lowering the manufacturing cost.

The electronic device 101 may further include a medium layer LC, the counter substrate OSB, a protection layer OC, and the shielding pattern BM3. The protection layer OC is disposed at a side of the counter substrate OSB facing the substrate SB. The medium layer LC is disposed between the counter substrate OSB and the substrate SB. The medium layer LC may include liquid crystal material. In other embodiments, the electronic device 101 may include light emitting diode display device, and the medium layer LC may include light emitting diode elements. The shielding pattern BM3 may be disposed in the second region R2, and the shielding pattern BM3 may be used to provide light shielding effect in the peripheral region of the electronic device 101. In some embodiments, the shielding pattern BM3 may be disposed on a side of the counter substrate OSB facing the substrate SB, and the protection layer OC may be disposed between the shielding pattern BM3 and the medium layer LC.

The substrate SB and the counter substrate OSB may include a rigid material or a flexible material. The rigid material may include glass or other suitable materials. The flexible material may include polyimide (PI), polycarbonate (PC), polyethylene terephthalate (PET), other suitable materials. The insulation layers IN1-IN7 may respectively include an organic insulation material or an inorganic insulation material. The first organic layer PL1 may include a low dielectric constant organic insulation material. The conductive layers M1, M2, M3, and M4 may include a metallic electrically conductive material, and the conductive layers CL, EL1, EL2, and EL3 may include a transparent metal oxide conductive material. The shielding patterns BM1, BM2, and BM3 may include black photoresist, black printing ink, a black resin, an organic resin, or a glass paste. In this disclosure, the shielding patterns BM1, BM2, the light filtering layer CF, and the first organic layer PL1 can be formed from photopatternable materials. This allows these layers and their respective openings (e.g., OP1, OP2, OP3) to be defined via photolithography, simplifying the manufacturing process.

The following description highlights the differences between various embodiments. To ensure clarity and brevity, common features are not repeated. For ease of comparison, like components are designated with the same reference numerals throughout the figures.

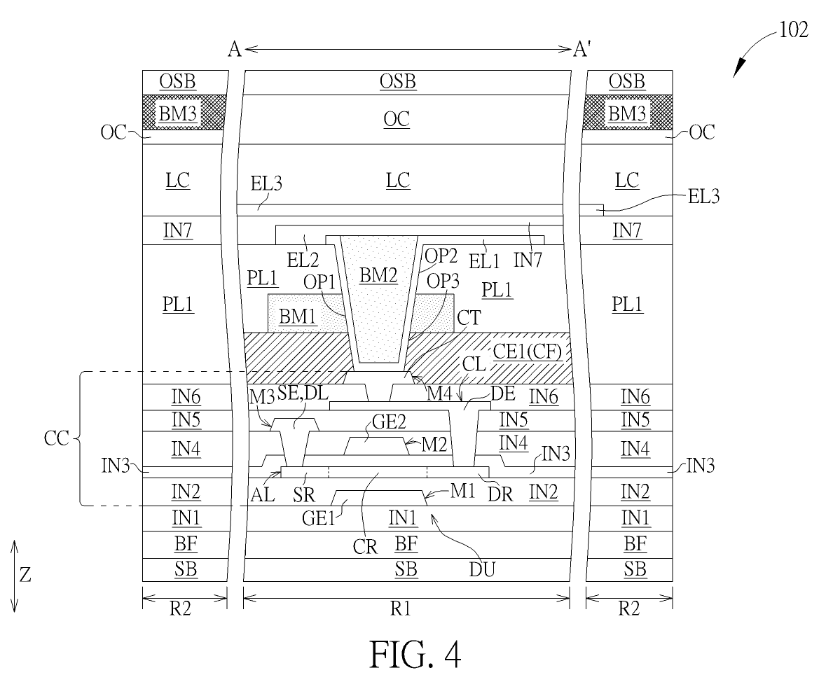

Please refer to FIG. 4. In an electronic device 102 according to a second embodiment, the shielding pattern BM1 may be disposed between the light filtering layer CF and the first organic layer PL1 accordingly. This allows the shielding pattern BM1 to be formed after the light filtering layer CF for avoiding negative influence on the manufacturing process for forming the light filtering layer CF.

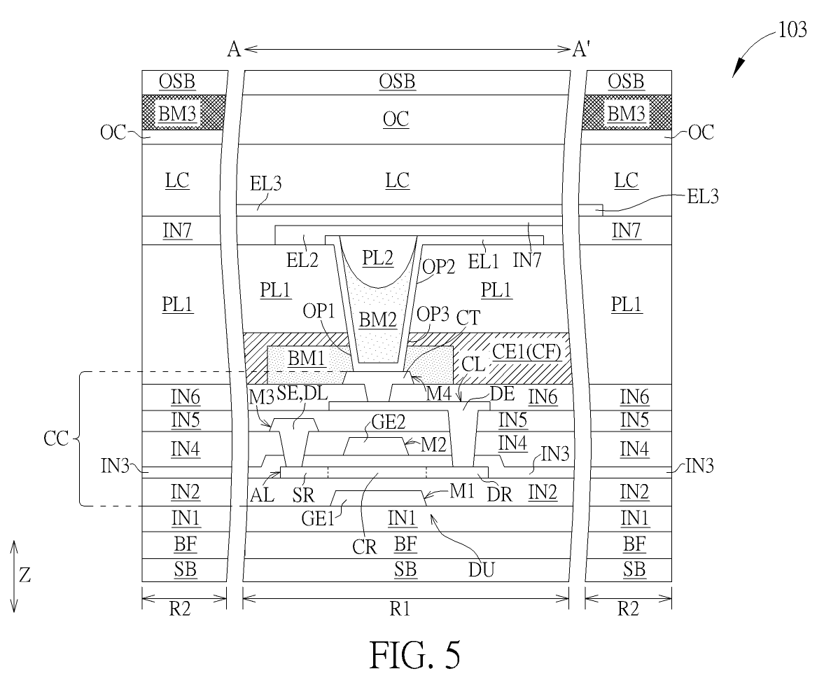

Please refer to FIG. 5. An electronic device 103 according to a third embodiment may further include a second organic layer PL2 disposed on the shielding pattern BM2 and disposed in the opening OP2. The shielding pattern BM2 may be disposed between the second organic layer PL2 and the conductive layer EL1, and a top surface of the second organic layer PL2 and the top surface of the conductive layer EL1 may be substantially coplanar. In some embodiments, the top surface of the second organic layer PL2 may be slightly higher or lower than the top surface of the conductive layer EL1, or even slightly lower than the top surface of the first organic layer PL1. The material composition of the second organic layer PL2 may be identical to or different from the material composition of the first organic layer PL1. The second organic layer PL2 may be disposed between the conductive layer EL2 and the shielding pattern BM2 for keeping the conductive layer EL2 from directly contacting the shielding pattern BM2, thereby reducing the influence of the shielding pattern BM2 on the material properties of the conductive layer EL2.

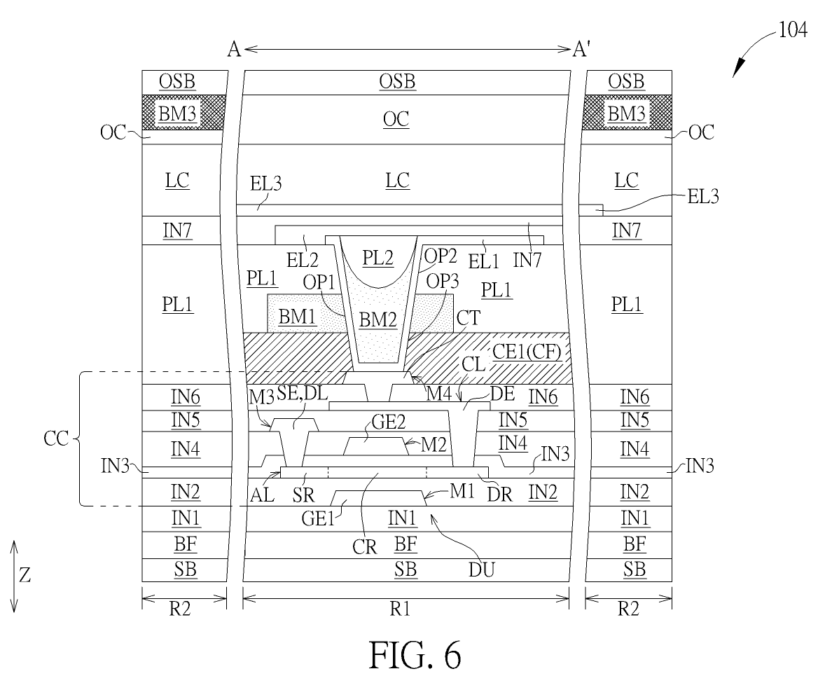

Please refer to FIG. 6. An electronic device 104 according to a fourth embodiment may further include the second organic layer PL2 disposed on the shielding pattern BM2 and disposed in the opening OP2. In addition, the shielding pattern BM1 may be disposed between the light filtering layer CF and the first organic layer PL1 accordingly.

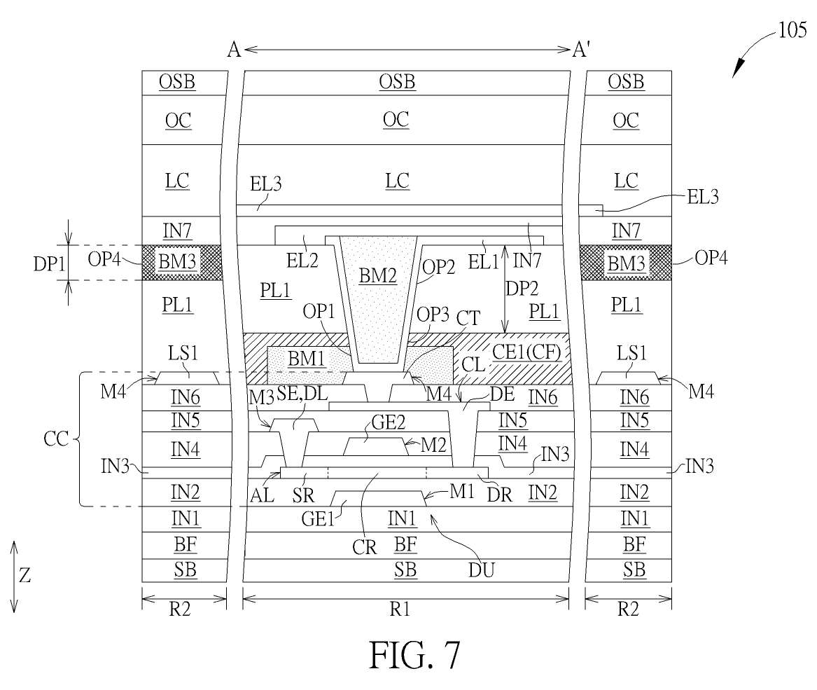

Please refer to FIG. 7. In an electronic device 105 according to a fifth embodiment, the first organic layer PL1 is disposed on the driving circuit DU and includes a first opening (such as an opening OP4) and a second opening (such as the opening OP2). The conductive layer EL1 is electrically connected with the driving circuit DU via the opening OP2. The shielding patterns BM3 and BM2 are disposed in the openings OP4 and OP2, respectively, and a depth of the opening OP4 (such as a depth DP1) is different from a depth of the opening OP2 (such as a depth DP2). The shielding pattern BM3 and the opening OP4 are disposed in the second region R2, the opening OP2 is disposed in the first region R1, and the depth DP2 of the opening OP2 is greater than the depth DP1 of the opening OP1. The opening OP4 may be a recess. In some embodiments, openings with different depths may be formed in the first organic layer PL1 by using a photo mask having regions with different light transmittances for performing an exposure and developing process, achieving process simplification and/or manufacturing cost reduction. In this embodiment, the shielding pattern BM3 is disposed in the opening OP4, and disposed between the insulation layer IN7 and the first organic layer PL1. The optical density of the shielding pattern BM3 disposed in the opening OP4 may be lower than that of the shielding pattern BM3 disposed on the counter substrate OSB. Therefore, in some embodiments, the electronic device 105 may include a shielding layer LS1 disposed on the insulation layer IN6 and disposed in the second region R2, and the shielding layer LS1 may overlap the shielding pattern BM3 in the direction Z for enhancing the light shielding effect in the second region R2. In some embodiments, the shielding layer LS1 may be a part of the conductive layer M4.

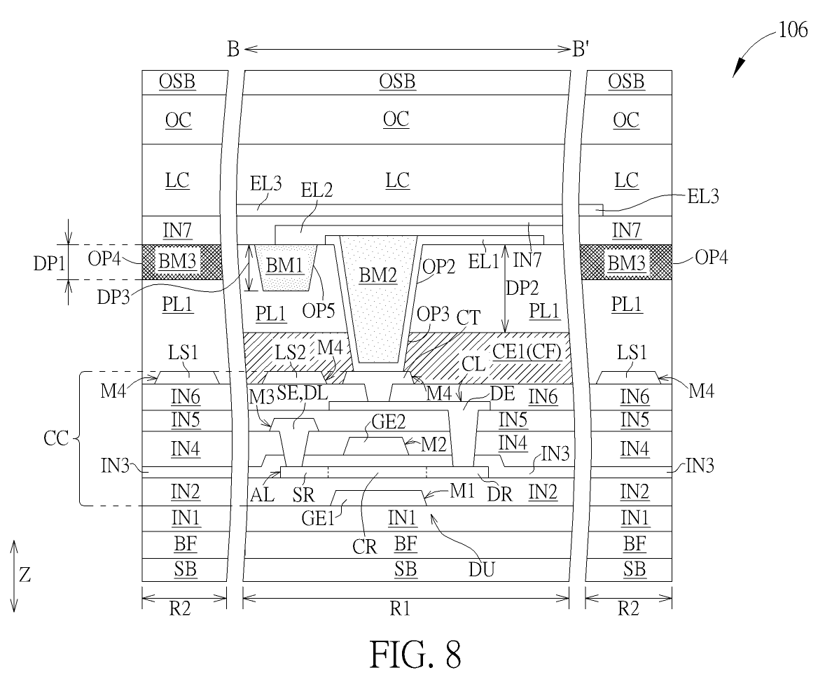

Please refer to FIG. 1, FIG. 2, and FIG. 8. In an electronic device 106 according to a sixth embodiment, the first organic layer PL1 may further include an opening OP5, and the shielding pattern BM1 may be disposed in the opening OP5. In some embodiments, a depth of the opening OP5 (such as a depth DP3) may be different from the depth DP2 of the opening OP2. For instance, the depth DP3 of the opening OP5 may be less than the depth DP2 of the opening OP2. The shielding pattern BM1 and the opening OP5 are disposed in the first region R1 and overlap the data line DL, and the shielding pattern BM1 and the opening OP5 may extend along the extending direction XD of the data line DL. The opening OP5 may be a recess, the first organic layer PL1 may be partly disposed between the shielding pattern BM1 and the light filtering layer CF, and the opening OP5 may be formed on a surface of the first organic layer PL1 away from the light filtering element CE1. The electronic device 106 may further include a shielding layer LS2 disposed on the insulation layer IN6 and disposed in the first region R1, the shielding layer LS2 may overlap the shielding pattern BM1 in the direction Z for compensating the negative influence generated by the greater distance between the shielding pattern BM1 and the data line DL when the shielding pattern BM1 is disposed in the opening OP5, and the shielding layer LS2 may be used to enhance the light shielding effect. In some embodiments, the shielding layer LS2 may be a part of the conductive layer M4.

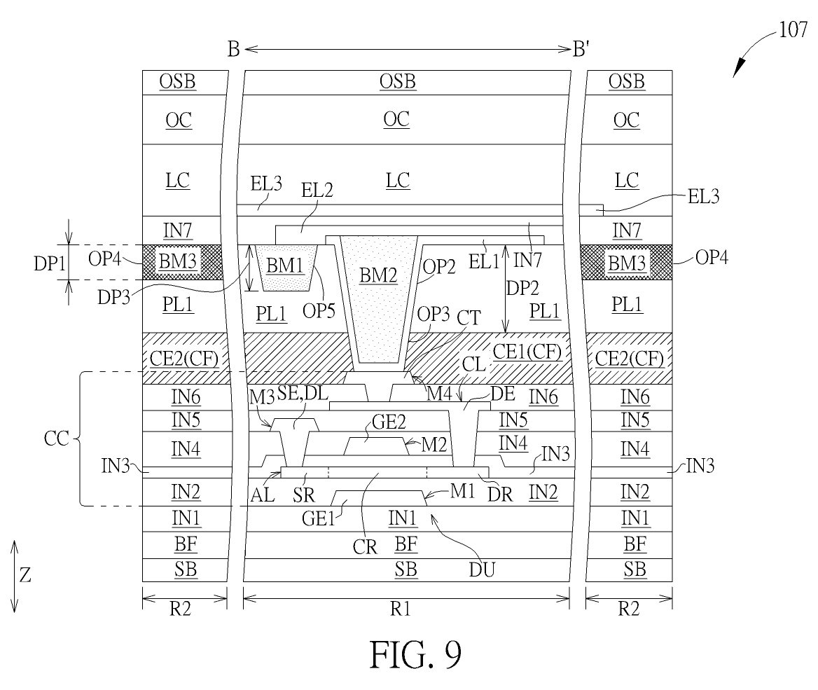

Please refer to FIG. 9. In an electronic device 107 according to a seventh embodiment, the light filtering layer CF may be further disposed partly in the second region R2, and the first organic layer PL1 may be partly disposed between the shielding pattern (such as BM1 and BM3) and the light filtering layer CF. The light filtering layer CF may include a light filtering element CE2 disposed in the second region R2.

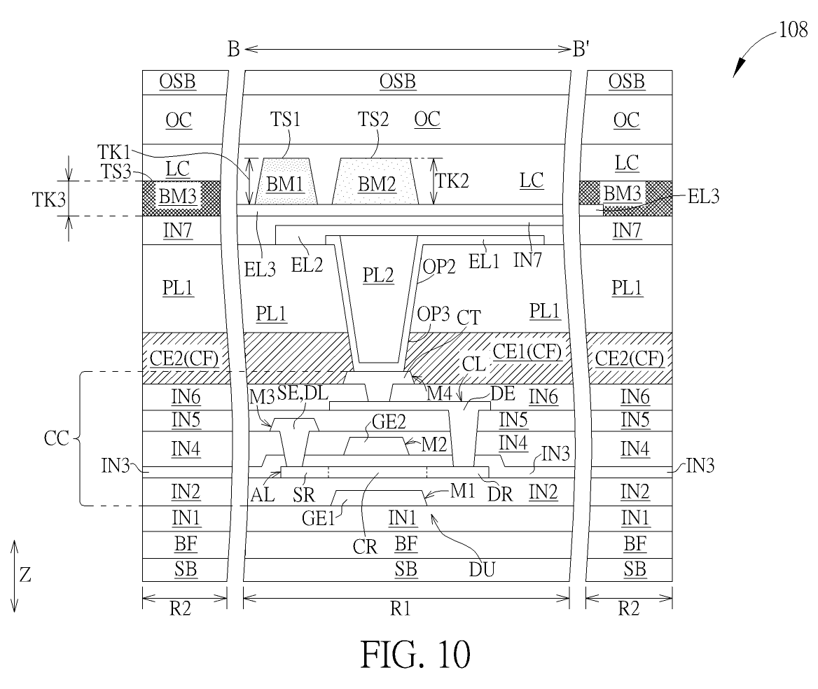

Please refer to FIG. 10. In an electronic device 108 according to an eighth embodiment, the shielding patterns BM1 and BM2 may be disposed on the insulation layer IN7, and as spacers for controlling the distance between the counter substrate OSB and the substrate SB. Therefore, the shielding pattern BM1 and BM2 may directly contact the medium layer LC. In some embodiments, the shielding pattern BM1 and BM2 may be disposed on the conductive layer EL3. In addition, a top surface TS1 of the shielding pattern BM1 may be at the same height as a top surface TS2 of the shielding pattern BM2, and a thickness TK1 of the shielding pattern BM1 in the direction Z may be substantially equal to or different from a thickness TK2 of the shielding pattern BM2.

Additionally, in some embodiments, the shielding pattern BM3 may be disposed between the medium layer LC and the insulation layer IN7. A top surface TS3 of the shielding pattern BM3 may be lower than the top surface TS1 of the shielding pattern BM1 and the top surface TS2 of the shielding pattern BM2, and a thickness TK3 of the shielding pattern BM3 in the direction Z may be less than the thickness TK1 of the shielding pattern BM1 and the thickness TK2 of the shielding pattern BM2 also. In other embodiments, the top surface TS3 of the shielding pattern BM3 may be higher than the top surface TS1 of the shielding pattern BM1 and the top surface TS2 of the shielding pattern BM2. In some embodiments, the material composition of the shielding pattern BM3 may be identical to the material composition of the shielding patterns BM1 and BM2, and the shielding patterns BM3, BM2, and BM1 may be formed concurrently by the same process. In some embodiments, when the shielding patterns BM1 and BM2 are disposed on the insulation layer IN7 and used as the spacers, the shielding pattern BM3 in the second region R2 may also be disposed on the counter substrate OSB. In addition, when the shielding patterns BM1, BM2, and BM3 are disposed on the insulation layer IN7, the design of the shielding layers LS1 and LS2 in FIG. 8 described above may also be applied for providing the required light shielding effect without disposing the light filtering layer in the second region R2.

To summarize the above descriptions, in the electronic device according to the present disclosure, the negative influence of the misalignment occurred during combining the substrate and the counter substrate, such as decreasing the aperture ratio, may be reduced by disposing the shielding patterns on a side of the array substrate. The distance between the shielding pattern and the material generating reflection may be further reduced by disposing the shielding pattern in the opening connecting the conductive layer and the driving circuit for enhancing the light shielding effect and/or simplifying the related manufacturing steps. The display quality of the electronic device may be improved and/or the manufacturing cost may be reduced accordingly.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a driving circuit disposed on the substrate;
a first shielding pattern disposed on the driving circuit and comprising a first opening;
a first organic layer disposed on the first shielding pattern and comprising a second opening overlapped with the first opening;
a conductive layer electrically connected with the driving circuit via the first opening and the second opening; and
a second shielding pattern disposed in the first opening and the second opening.

2. The electronic device according to claim 1, further comprising:
a light filtering layer disposed between the first shielding pattern and the first organic layer.

3. The electronic device according to claim 1, further comprising:
a light filtering layer, wherein the first shielding pattern is disposed between the light filtering layer and the first organic layer.

4. The electronic device according to claim 1, further comprising:
a second organic layer disposed on the second shielding pattern and disposed in the second opening.

5. The electronic device according to claim 1, further comprising:
a light filtering layer, wherein the light filtering layer comprises a third opening overlapped with the second opening, and the second shielding pattern is disposed in the third opening.

6. An electronic device, comprising:
a substrate;
a driving circuit disposed on the substrate;
a first organic layer disposed on the driving circuit and comprising a first opening and a second opening;
a conductive layer electrically connected with the driving circuit via the second opening; and
a first shielding pattern and a second shielding pattern disposed in the first opening and the second opening, respectively, wherein a depth of the first opening is different from a depth of the second opening.

7. The electronic device according to claim 6, wherein the driving circuit comprises a data line, the first opening is overlapped with the data line, and the first opening extends along an extending direction of the data line.

8. The electronic device according to claim 6, wherein the first opening is disposed in a peripheral region.

9. The electronic device according to claim 8, further comprising:
a light filtering layer, wherein the first organic layer is disposed between the first shielding pattern and the light filtering layer.

10. The electronic device according to claim 6, further comprising:
a light filtering layer, wherein the light filtering layer comprises a third opening overlapped with the second opening, and the second shielding pattern is disposed in the third opening.
